(19) United States
(12) Patent Application Publication
(10) Pub. No.: US 2024/0157446 A1
(43) Pub. Date: May 16, 2024

(54) Selective Modification of Nanoparticle Structures

(71) Applicant: Mesoline Inc., Matthews, NC (US)

(72) Inventors: Marnix P. Rebergen, Rotterdam (NL); Serhii Mytnyk, Capelle aan den IJssel (NL); Saleh Aghajani, Rijswijk (NL)

(73) Assignee: Mesoline Inc., Matthews, NC (US)

(21) Appl. No.: 18/505,960

(22) Filed: Nov. 9, 2023

Related U.S. Application Data
(60) Provisional application No. 63/383,198, filed on Nov. 10, 2022.

(51) Int. Cl. B22F 10/66; B22F 10/28; B33Y 10/00; B33Y 40/20

(52) U.S. Cl. CPC B22F 10/66; B22F 10/28; B33Y 10/00; B33Y 40/20; B22F 2304/054; B22F 2304/056; B22F 2304/058; B22F 2304/10

(57) ABSTRACT

Systems and methods for selective modification of nanoparticle structures are described. The selective modification processes include applying a localized heat source to the deposited nanoparticle structures and removing the areas that are not activated by the localized heat.

### CROSS-REFERENCE TO RELATED APPLICATIONS

The current application claims the benefit, under 35 U.S.C. § 119(e), of U.S. Provisional Patent Application No. 63/383,198 entitled “Selective Removal of Micro-Molded Nanoparticle Structures” filed Nov. 10, 2022. The disclosure of U.S. Provisional Patent Application No. 63/383,198 is incorporated by reference in its entirety for all purposes.

### FIELD OF INVENTION

The present disclosure relates to the selective modification of nanoparticle structures, more particularly relates to selective sintering and removing of micro-molded nanoparticle structures.

### BACKGROUND

Nanoparticle coatings are applied in a variety of electronic devices such as gas sensors, biosensors, getters, and printed electronics. Nanoparticle coatings can serve various functions in electronic devices such as: as a sensing element of the devices, as a protective coating to absorb gasses, or to form part of an electronic circuit. Nanoparticle coatings may be applied using a variety of methods such as screen-printing, inkjet deposition, aerosol jet printing, dip-coating, spin-coating, and micro-molding.

### BRIEF SUMMARY

Systems and methods for selectively modifying free-standing nanoparticle structures on various surfaces are described.

Some embodiments include a method for selectively modifying nanoparticle structures, comprising: depositing a structure of a continuous pattern comprising nanoparticles on a substrate; applying a heat to a first portion of the structure, wherein the heat selectively sinters the nanoparticles in the first portion; and removing nanoparticles that are not sintered such that the sintered first portion of the structure forms a discrete pattern.

In some embodiments, the structure of continuous pattern is deposited by a micro-molding process, a microchannel particle deposition process, a screen-printing process, a spin coating process, a blade coating process, an ink-jet printing process, or an aerosol jet printing process.

In some embodiments, the heat is a localized heat provided by a micro hotplate, a masked light source, a UV light source, a masked UV source, a visible light source, an infrared light source, a laser, a focused laser beam, or a magnetic induction.

In some embodiments, the heat is a localized heat provided by a UV light with a wavelength that matches a plasmonic frequency of the nanoparticles.

In some embodiments, the laser has a wavelength range selected from the group consisting of: from 100 nm to 400 nm, from 380 nm to 700 nm, and from 780 nm to 1 mm; wherein the laser has a pulsation condition selected from the group consisting of: a continuous wave laser, a nanosecond laser, a picosecond laser, and a femtosecond laser.

Some embodiments further comprise heating the substrate up to 150° C. to remove non-nanoparticle substances prior to applying the heat.

In some embodiments, the heat is between 100° C. and 1000° C.

In some embodiments, the nanoparticles comprise metal nanoparticles, metal-oxide nanoparticles, metal alloy nanoparticles, or any combinations thereof.

In some embodiments, the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt.

In some embodiments, the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxide.

In some embodiments, the nanoparticles have an average diameter between 1 nm and 10 microns.

In some embodiments, the continuous pattern further comprises at least one material selected from the group consisting of: dispersants, binders, polymers, solids, and solvent residues.

In some embodiments, removing is a chemical removal process or a mechanical removal process.

In some embodiments, the chemical removal process comprises a solvent selected from the group consisting of: water, isopropanol, acetone, ethanol, ethylene glycol, methyl ethyl ketone, diethylene glycol monomethyl ether, dimethyl sulfoxide, trichloroethylene, tetrachloroethylene, hexane, toluene, sodium hydroxide, potassium hydroxide, acetic acid, citric acid, and a combination thereof.

In some embodiments, the solvent comprises a surfactant selected from the group consisting of: an anionic surfactant, a nonionic surfactant, a cationic surfactant, an amphoteric surfactant, and a combination thereof.

In some embodiments, the mechanical removal process comprises using ultrasonic energy or peeling with an adhesive layer.

In some embodiments, a minimum distance among the discrete pattern is between 1 micrometer and 100 micrometers.

In some embodiments, the substrate comprises one or more functional electronic elements and the discrete pattern does not overlap with the one or more functional electronic elements.

Some embodiments include a method for selectively modifying nanoparticle structures, comprising: depositing a structure of a continuous pattern comprising nanoparticles on a substrate; applying an adhesive mask onto the structure; applying a heat to a first portion of the adhesive mask, wherein the heat selectively activates the adhesives in the first portion such that the first portion of the adhesive mask binds to the nanoparticles; and removing the nanoparticles of the first portion by removing the adhesive mask such that a remaining portion forms a discrete pattern.

In some embodiments, the structure of continuous pattern is deposited by a micro-molding process, a microchannel particle deposition process, a screen-printing process, a spin coating process, a blade coating process, an ink-jet printing process, or an aerosol jet printing process.

In some embodiments, the heat is a localized heat provided by a micro hotplate, a masked light source, a UV light source, a masked UV source, a visible light source, an infrared light source, a laser, a focused laser beam, or a magnetic induction.

In some embodiments, the heat is a localized heat provided by a UV light with a wavelength that matches a plasmonic frequency of the nanoparticles.

In some embodiments, the laser has a wavelength range selected from the group consisting of: from 100 nm to 400 nm, from 380 nm to 700 nm, and from 780 nm to 1 mm; wherein the laser has a pulsation condition selected from the group consisting of: a continuous wave laser, a nanosecond laser, a picosecond laser, and a femtosecond laser.

In some embodiments, the nanoparticles comprise metal nanoparticles, metal-oxide nanoparticles, metal alloy nanoparticles, or any combinations thereof.

In some embodiments, the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt.

In some embodiments, the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxide.

In some embodiments, the nanoparticles have an average diameter between 1 nm and 10 microns.

In some embodiments, the continuous pattern further comprises at least one material selected from the group consisting of: dispersants, binders, polymers, solids, and solvent residues.

In some embodiments, a minimum distance among the discrete pattern is between 1 micrometer and 100 micrometers.

Additional embodiments and features are set forth in part in the description that follows, and in part will become apparent to those skilled in the art upon examination of the specification or may be learned by the practice of the disclosure. A further understanding of the nature and advantages of the present disclosure may be realized by reference to the remaining portions of the specification and the drawings, which forms a part of this disclosure.

### BRIEF DESCRIPTION OF THE DRAWINGS

The description and claims will be more fully understood with reference to the following figures and data graphs, which are presented as exemplary embodiments of the invention and should not be construed as a complete recitation of the scope of the invention.

FIGS. 1A-1D illustrate micro-molding stamps in accordance with prior art.

FIGS. 2A-2E illustrate selective modification of micro-molded nanoparticle structures in accordance with an embodiment.

FIGS. 3A-3B illustrate selective removal of micro-molded nanoparticle structures from sensitive areas in accordance with an embodiment.

FIG. 4 illustrates a process for selective modification of micro-molded nanoparticle structures in accordance with an embodiment.

FIG. 5 illustrates a setup for selective modification of micro-molded nanoparticle structures in accordance with an embodiment.

FIGS. 6A-6B illustrate alternative setups for selective modification of micro-molded nanoparticle structures in accordance with an embodiment.

FIG. 7 illustrates an alternative setup for selective modification of micro-molded nanoparticle structures in accordance with an embodiment.

FIG. 8 illustrates a washing process for selective removal of micro-molded nanoparticle structures in accordance with an embodiment.

FIGS. 9A-9B illustrate scanning electron microscope images of selectively modified micro-molded nanoparticle structures in accordance with an embodiment.

FIGS. 10A-10C illustrate nanoparticles of various morphology and structures after selective modification in accordance with an embodiment.

### DETAILED DESCRIPTION

Systems and methods for selectively modifying free-standing nanoparticle structures deposited by (but not limited to) micro-molding processes or microchannel particle deposition (MPD) on various surfaces such as (but not limited to) surfaces comprising semiconductor materials or wafers are described. Many embodiments implement local sintering processes to modify deposited nanoparticle structures in order to achieve the desired structures, geometries, and/or morphologies. In several embodiments, convention sintering steps of nanoparticles can be omitted. Local sintering processes provide precision treatment to nanoparticle structures to remove undesired artifacts. In some embodiments, various local heat sources such as (but not limited to) lasers and/or UV lights can be used for sintering. Local sintering processes in accordance with some embodiments enable a wide range of treatment temperatures based on the wavelength of laser and/or light used. In certain embodiments, local sintering can achieve feature sizes in micron and millimeter ranges. Several embodiments implement washing processes to remove un-sintered structures.

In many embodiments, micro-molding processes or MPD can be used to deposit nanoparticle structures. Local sintering of MPD deposited features in accordance with various embodiments enables the patterning of discrete features from a single set of MPD inlet and outlet ports. Such processes can broaden the applicability of the MPD processes and the compatibility with processes such as (but not limited to) stealth dicing.

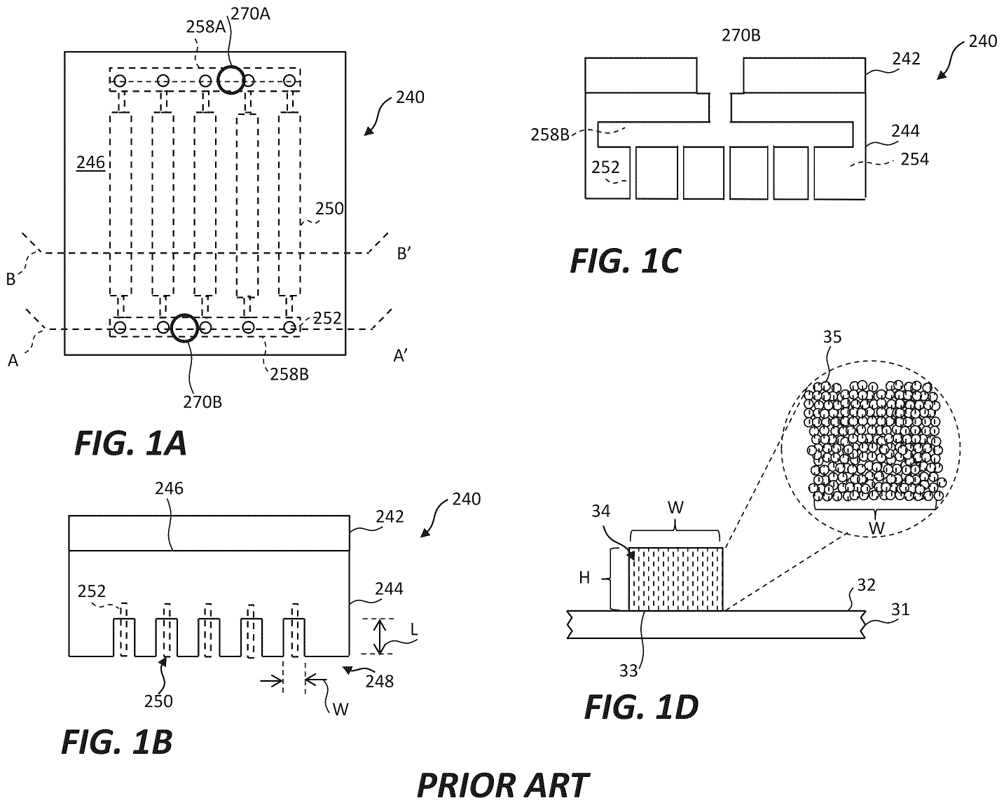

The micro-molding processes or MPD processes implement elastomeric stamps to deposit structures on a surface. (See, e.g., U.S. Patent Publication No. US20210381994A1 to Rebergen et al., the disclosure of which is incorporated by reference by its entirety.) A micro-molding stamp is illustrated in FIGS. 1A through 1C. FIG. 1A illustrates a top view of the stamp. FIG. 1B shows a cross section view of the BB′ plane in FIG. 1A. FIG. 1C shows a cross section view of the AA′ plane in FIG. 1A. Micro-molding stamp 240 comprises a mold layer 244 having a support side 246 and a channel side 248. A support layer 242 is disposed in contact with support side 246. Support layer 242 can be more rigid than mold layer 244 to provide dimensional stability to mold layer 244 and enable improved resolution for structures formed by micro-molding stamp 240. Mold layer 244 can comprise a plurality of microscopic grooves and/or channels 250 disposed on the channel side 248 in mold layer 244. The channels can have an average width W ranging from about 1 micron to about 500 microns. The width W and height L of the channels may be the same or different, and the cross-sectional shape of the channel may vary along its length.

Inlet ports 270A embedded in the support layer 242 can be connected to the plurality of channels and/or grooves 250. Each of the inlet ports is connected to at least one of the channels. Inlet ports can be connected with syringes and/or pumps (not shown) to pump inks into the channels 250. Ink comprising nanoparticle materials can be pumped through inlet ports 270A into one or more inlet reservoirs 258A embedded in the mold layer 244. The ink reservoirs 258A/B connect to one or more grooves 250 via one or more through holes 252. In some embodiments ink reservoirs 258A/B comprise channels embedded in the stamp, which together serve as an ink distribution network. To facilitate ink flow through the grooves 250, the plurality of grooves 250 are connected via through-holes 252 in the mold layer to one or more outlet reservoirs 258B which are in turn connected to one or more outlet ports 270B. Ink can flow through the channels and/or grooves by capillary action and/or applied pressure to the inlet ports. In some embodiments, ink reservoirs 258A and/or 258B may comprise various layouts, geometries, and/or designs to facilitate the distribution of ink to different layouts of the grooves/channels 250 or to supply different inks/materials to different sets of grooves. Vacuum can be applied to the outlet ports to facilitate the flow.

During the micro-molding processes, micro-molding elastomeric stamps 240 containing the microscopic grooves 250 can be brought in contact with a substrate surface. The microscopic grooves 250 form channels on the substrate surface. Subsequently, a suspension loaded with nanoparticles such as (but not limited to) nanoparticle ink, can be injected into the channels. The suspension can then be cured in contact with the substrate surface. In this disclosure, the term “curing” refers to the removal of solvents from the ink, leaving behind a dried structure comprising (mainly) solids, such as nanoparticles and polymers. After removing the stamp, the dried/semi-dried nanoparticles remain on the substrate surface at the position of the grooves in the stamp, concluding micro-molding processes. The cross-section of the remaining features is determined by the grooves in the stamp. Once the curing is complete, the remaining non-nanoparticle substances in the structure can be removed through evaporation, decomposition, degradation, and/or a combination thereof. The patterned structures are heated to sinter and/or to complete the curing procedure of the nanoparticles. In this disclosure, the term “sintering” refers to the combination of physical, chemical, and mechanical bonding and interlocking of nanoparticles to each other and as a whole to the substrate. FIG. 1D illustrates the cross-section of a micro-molded nanoparticle feature on a substrate. A feature 34 can be deposited via micro-molding onto one surface 32 of a substrate 31, having a contact area or footprint 33. The feature 34 comprising nanoparticles 35 can have width W and height H. The width W can range from about 1 micron to about 500 microns. The height H can range from about 1 micron to about 500 microns. The feature 34 can have a high aspect ratio in order to reduce the footprint and/or size on microelectronic devices. The aspect ratio can be between about 0.05 and about 50, where the width W is less than the length L.

The sintering processes can have various outcomes depending on the desired applications and properties including: a) nanoparticles forming a small attaching area while preserving their general form and shape; b) nanoparticles partially merging while keeping their partial micro and nanostructure and boundaries; c) nanoparticles completely merging and forming new shapes and/or structures; and/or d) smaller nanoparticles merge into larger particles, while larger particles keep their general forms and shapes. The micro-molding processes can form well-defined and microscopic structures made of nanoparticles. Such nanoparticle structures can be patterned directly onto wafers and/or any substantially flat substrates that contain microelectronic devices.

The micro-molding stamps require the presence of one or more inlet and outlet ports through which nanoparticle-loaded ink can be supplied to the microscopic grooves and to be deposited onto the substrate. The nanoparticle ink can be injected into the inlet ports. The ink then flows through the channels formed between the stamp and substrate, and exits through the outlet ports. The requirement for these ports in the stamp can limit the applicability of the micro-molding processes to create features that are continuously connected between two points. The start and end points of the features correspond to a single pair of inlet and outlet ports within the stamp. Such limitation can further limit a minimum distance between discretely patterned areas to the minimum distance between inlet and outlet ports. In addition, the micro-molding processes require that microscopic grooves which are separately connected between the same pair of inlet and outlet ports have a similar order of magnitude flow resistance and/or pressure drop. Finally, the design of the microscopic grooves need to ensure that they contain no sharp bends to prevent pinning of the fluid-gas interface. These constrains can limit the design patterns and/or features that can be deposited using the micro-molding processes.

To overcome such limitations, many embodiments provide micro-molding processes that can achieve patterning of discrete features on a surface. The micro-molding processes in accordance with several embodiments enable local modification of micro-molded structures to achieve desired geometries, (micro)structures, morphology, and/or pore density. In various embodiments, selective removal of nanoparticle structures can be combined with the micro-molding processes to achieve local modification of the structures. During the micro-molding processes, curing of the nanoparticle ink forms continuous micro-molded structures. The selective nanoparticle sintering and removal processes in accordance with various embodiments sinter nanoparticles in selected areas on the substrate surface, the un-sintered nanoparticles can be removed such that it forms discrete features on the substrate surface.

In certain embodiments, selective removal processes for nanoparticles on a substrate surface can be applied after deposition of the nanoparticles by methods such as (but not limited to) screen-printing, spin-coating, blade-coating, ink-jet printing, and aerosol-jet printing, in addition to micro-molding.

In some embodiments, local removal of nanoparticles can be achieved by locally heating micro-molded structures to sinter nanoparticles in desired areas after which un-sintered particles are removed by washing. Local heating can be achieved using (but not limited to): heaters that are incorporated in the substrate; micro-hotplates; micro-hotplates incorporated in the substrate; magnetic induction; masked or patterned light sources; masked or patterned UV sources (wavelength from about 100 nm to about 400 nm), light sources of visible wavelength ranges (from about 380 nm to about 700 nm), light sources of infrared (IR) wavelength ranges (from about 780 nm to about 1 mm), lasers of UV wavelengths (wavelength from about 100 nm to about 400 nm), lasers of visible wavelength ranges (from about 380 nm to about 700 nm), lasers of IR wavelength ranges (from about 780 nm to about 1 mm), and/or any combinations thereof. In various embodiments, localized heating can be applied by UV light sources such as lasers or lamps with wavelengths that match the plasmonic frequency of the micro-molded nanoparticle. In some embodiments, the laser sources can work under continuous wave (CW), nanoseconds, picoseconds, and/or femtoseconds pulsation conditions while employing various wavelengths. Examples of laser wavelengths include (but not limited to) from about 100 nm to about 1 mm; or from about 200 nm to about 1 mm; or from about 300 nm to about 1 mm; or from about 400 nm to about 1 mm; or from about 500 nm to about 1 mm; or from about 600 nm to about 1 mm; or from about 700 nm to about 1 mm; or from about 800 nm to about 1 mm; or from about 900 nm to about 1 mm; or from about 1000 nm to about 1 mm; or from about 1100 nm to about 1 mm; or from about 1200 nm to about 1 mm; or from about 1300 nm to about 1 mm; or from about 1400 nm to about 1 mm; or from about 1500 nm to about 1 mm; or from about 1600 nm to about 1 mm; or from about 1700 nm to about 1 mm; or from about 1800 nm to about 1 mm; or from about 1900 nm to about 1 mm; or from about 2000 nm to about 1 mm; or from about 3000 nm to about 1 mm; or from about 4000 nm to about 1 mm; or from about 5000 nm to about 1 mm; or about 193 nm; or about 213 nm; or about 223 nm; or about 244 nm; or about 257 nm; or about 273 nm; or about 289 nm; or about 303 nm; or about 335 nm; or about 351 nm; or about 355 nm; or about 360 nm; or about 375 nm; or about 395 nm; or about 397 nm; or about 400 nm; or about 405 nm; or about 415 nm; or about 420 nm; or about 430 nm; or about 434 nm; or about 438 nm; or about 440 nm; or about 445 nm; or about 454 nm; or about 457 nm; or about 460 nm; or about 470 nm; or about 473 nm; or about 480 nm; or about 484 nm; or about 488 nm; or about 491 nm; or about 496 nm; or about 501 nm; or about 514 nm; or about 515 nm; or about 522 nm; or about 523 nm; or about 526 nm; or about 530 nm; or about 532 nm; or about 536 nm; or about 540 nm; or about 543 nm; or about 550 nm; or about 552 nm; or about 556 nm; or about 561 nm; or about 577 nm; or about 589 nm; or about 593 nm; or about 601 nm; or about 607 nm; or about 612 nm; or about 620 nm; or about 622 nm; or about 639 nm; or about 640 nm; or about 650 nm; or about 656 nm; or about 660 nm; or about 666 nm; or about 669 nm; or about 671 nm; or about 678 nm; or about 689 nm; or about 698 nm; or about 721 nm; or about 730 nm; or about 750 nm; or about 755 nm; or about 758 nm; or about 760 nm; or about 775 nm; or about 790 nm; or about 800 nm; or about 808 nm; or about 820 nm; or about 825 nm; or about 850 nm; or about 852 nm; or about 860 nm; or about 870 nm; or about 879 nm; or about 880 nm; or about 885 nm; or about 905 nm; or about 912 nm; or about 915 nm; or about 940 nm; or about 946 nm; or about 975 nm; or about 976 nm; or about 980 nm; or about 1020 nm; or about 1030 nm; or about 1047 nm; or about 1064 nm; or about 1073 nm; or about 1080 nm; or about 1085 nm; or about 1105 nm; or about 1122 nm; or about 1160 nm; or about 1178 nm; or about 1202 nm; or about 1240 nm; or about 1313 nm; or about 1319 nm; or about 1335 nm; or about 1357 nm; or about 1413 nm; or about 1444 nm; or about 1484 nm; or about 1535 nm; or about 1573 nm; or about 1645 nm; or about 1910 nm; or about 2096 nm; or about 2117 nm; or about 2200 nm; or about 2600 nm; or about 2700 nm; or about 2796 nm; or about 2830 nm; or about 2940 nm; or about 3000 nm; or about 3100 nm; or about 3390 nm; or about 3600 nm; or about 3800 nm; or about 4000 nm; or about 4200 nm; or about 4500 nm; or about 4600 nm; or about 4800 nm; or about 5260 nm; or about 6230 nm; or about 7830 nm; or about 9600 nm; or about 10600 nm. The lasers can operate in single or multi mode in some embodiments. Several embodiments implement more than one wavelength of laser in localized removal processes.

Local heating in accordance with some embodiments can cause the affected nanoparticles to sinter or cure in the areas that are exposed to heat or radiation. In some embodiments, nanoparticles can be heated to temperatures between about 100° C. and about 1000° C. In various embodiments, local sintering can form sintered areas with a linear dimension between about 1 micrometer and about 10 micrometers; or between about 5 micrometers and about 100 micrometers. In some embodiments, before local sintering, global heating can be optionally applied to all the micro-molded nanoparticles up to about 150° C. to reduce or remove the non-nanoparticle substances in order to achieve complete curing.

In a number of embodiments, nanoparticles that have not been sintered can be removed chemically, physically, and/or mechanically. In some embodiments, chemical removal of un-sintered particles can use a mixture of polar solvents, non-polar solvents, acids, and/or bases. Examples of solvents or etchants include (but are not limited to) water, isopropanol, acetone, ethanol, ethylene glycol, methyl ethyl ketone, diethylene glycol monomethyl ether, dimethyl sulfoxide, trichloroethylene, tetrachloroethylene, hexane, toluene, sodium hydroxide, potassium hydroxide, acetic acid, citric acid, and any combinations thereof. To improve the removal efficiency of un-sintered nanoparticles, surfactants may be added to the solvents. Examples of surfactants include (but are not limited to): anionic surfactants, nonionic surfactants, cationic surfactants, amphoteric surfactants, sodium dodecyl sulfate, sodium dodecylbenzene sulfonate, ammonium lauryl sulfate, trimethylnonylphenyl ether, polyethylene glycol tertoctylphenyl ether, cetylpyridinium chloride, benzalkonium chloride, octyltrimethylammonium bromide, cetyltrimethylammonium bromide, cocamidopropyl betaine, lauryldimethylamine N-oxide, lecithin, polyoxyethylene sorbitan monolaurate, polyethylene glycol hexadecyl ether, sorbitan monostearate, sorbitan tristearate, sorbitan monolaurate, sorbitan trioleate, and any combinations thereof. In some embodiments, following the chemical nanoparticle removal step, the substrate containing the remaining sintered structures can be optionally heated to above room temperature (for example to temperatures between about 100° C. and about 700° C.) to evaporate solvent residuals, and/or to achieve increased homogenization of the remaining structures on the substrate surface. Several embodiments implement physical or mechanical removal of un-sintered nanoparticles from the substrate. Examples of physical or mechanical removal include (but are not limited to) using an ultrasonic cleaner or plasma.

Many embodiments implement various selective modification processes to achieve desired nanoparticle features. In various embodiments, selective removal of nanoparticles can be achieved before the nanoparticles are sintered. Some embodiments incorporate a release agent that is activated upon exposure to a certain stimulus such as UV light or heat. The stimulus can be applied by (but not limited to) a laser or a micro-hotplate. Exposed parts of the structures can then be dissolved or rinsed/washed away using a solvent. Examples of solvents include (but are not limited to) demineralized water, ethanol, hexane, or ethylene glycol. After the washing step, the remaining structures are sintered by heating the substrate, for example using an oven, infrared lamp, or a laser.

In several embodiments, an adhesive mask can be applied after micro-molding and before sintering. The adhesive mask can mechanically bind to the micro-molded features. In some embodiments, the adhesives may be activated after deposition of the mask by locally exposing parts of the mask to UV radiation, for example by using a UV laser. Upon removal of the adhesive mask, particles can then be removed in selected areas that were in contact with the mask.

In some embodiments, a layer of photoresist can be applied to the substrate, which can then be patterned to remove the resist in select areas. Micro-molding is then performed on top of the patterned photoresist layer to deposit nanoparticle features. The deposited nanoparticle features can then be sintered. The nanoparticle features can then be removed by stripping the photoresist, in the manner of a lift-off process.

In some embodiments, selectively sintered micro-structures comprise nanoparticles containing at least one material including (but not limited to) micro-porous silica, meso-porous silica, silicon dioxide, porous glass, activated carbon, synthetic zeolites, natural zeolites (such as, molecular sieves 3A, 4A, 5A, 10X, 13X), aluminosilicate minerals and clays (such as montmorillonite, halloysite), metal oxide, copper oxide, palladium oxide, platinum oxide, and iron oxide. In several embodiments, micro-molded features comprise metals, metal alloys, and/or metal oxides including at least one metal element including (but not limited to) aluminum (Al), yttrium (Y), lanthanum (La), iron (Fe), molybdenum (Mo), tantalum (Ta), tungsten (W), niobium (Nb), manganese (Mn), chromium (Cr), titanium (Ti), zirconium (Zr), nickel (Ni), zinc (Zn), tin (Sn), cerium (Ce), palladium (Pd), cobalt (Co), platinum (Pt), silver (Ag), copper (Cu) and gold (Au). In certain embodiments, nanoparticles comprise at least one metal, metal alloy, and/or metal oxide/nitride/sulfide of aforementioned materials or combinations thereof.

In further embodiments, nanoparticle packing density and/or pore size can be controlled. Some embodiments select nanoparticles of specific geometries for the ink. Examples of nanoparticle geometries include (but are not limited to), tubes, nanowires, sheets, cubes, rods, platelets, cubes, various polyhedral and any combinations thereof. Several embodiments incorporate filler materials such as polymers into the ink. After sintering, the filler materials can form inert cavities or domains within micro-molded structures. In some embodiments, micro-molded structures may have an average pore size and/or cavity size ranging from about 0.1 nm to about 500 nm; or from about 1 nm to about 400 nm; or from about 5 nm to about 300 nm; or from about 5 nm to about 200 nm; or from about 1 nm to about 100 nm; or from about 0.1 nm to about 50 nm; or from about 0.1 nm to about 10 nm.

In various embodiments, selectively sintered micro-structures of different or same materials may be micro-molded onto a single device in one or more steps by using different sets of microscopic grooves combined with selective sintering. Each set of the microscopic grooves can be used to pattern a different or the same material.

In further embodiments, multiple layers of nanoparticle material may be deposited onto previously micro-molded structures to form a multi-layer structure. This may be achieved by performing multiple iterations of the micro-molding process, such as (but not limited to) using different inks and stamps. Some embodiments may use thin-film deposition methods such as evaporation or sputtering to deposit some of the layers. Selective sintering can be applied after the deposition of each material in accordance with some embodiments.

Selective sintered microstructures may contain various structures and topographic steps. In some embodiments, selective sintered microstructures may be formed around and/or onto structures and/or surfaces of microelectronic devices or onto a wafer containing microelectronic devices. In some embodiments, topographic steps may include constructing conductor traces and/or etched trenches.

In certain embodiments, selective sintered microstructures can be formed in specific shapes, discrete patterns, and/or structures. The selective sintered microstructures can have a shape of: a column, a cube, a strip, a patch, a cuboid, a dot, a polyhedron, a sphere, a polygon, an oval, a square, a triangle, a tube, a cylinder, and any combinations thereof. The selective sintered microstructures can have flat surfaces. A plurality of selective sintered microstructures can be arranged in arrays, in grids, in parallel lines, and/or randomly. The selective sintered microstructures can have discrete patterns. A distance between the discrete selective sintered microstructures can vary from about 1 micron to about 1 mm; or from about 1 microns to about 10 microns; or from about 10 microns to about 20 microns; or from about 20 microns to about 30 microns; or from about 30 microns to about 40 microns; or from about 40 microns to about 50 microns; or from about 50 microns to about 60 microns; or from about 60 microns to about 70 microns; or from about 70 microns to about 80 microns; or from about 80 microns to about 90 microns; or from about 90 microns to about 100 microns; or from about 100 microns to about 1 mm.

In many embodiments, selective modification processes improve the compatibility of the micro-molding processes with semiconductor packaging processes such as laser/stealth dicing (See, e.g., U.S. Pat. No. 9,548,246B2 to Fujii et al.; the disclosure of which is incorporated by reference), in which the presence of a nanoparticle coating in the dicing streets cab affect the functioning of the process. In some embodiments, selective sintering can be applied to reduce the thermal and/or mechanical strain on micro-molded nanoparticle features. For example, selective sintering can remove thermal or mechanical connections between neighboring areas on the substrate, and/or remove the connections between a suspended membrane and the surrounding area on the die. In several embodiments, selective sintering can be applied to control the morphology and porosity of the deposited nanoparticles. Controlling the local temperature and/or time duration of sintering allows for modification of the surface and bulk morphology together with the level of porosity. For example, fast heat-up allows for inducing necking in nanoparticles without the presence of a surface or bulk diffusion, enabling a highly porous and internally connected network of nanoparticles in desired regions. Fast heat up also allows sintering of features to temperatures exceeding the thermal limit of the substrate on which they are deposited. Increasing the time duration of sintering can allow surface and bulk diffusion which decreases porosity but increases the density of the networks of nanoparticles.

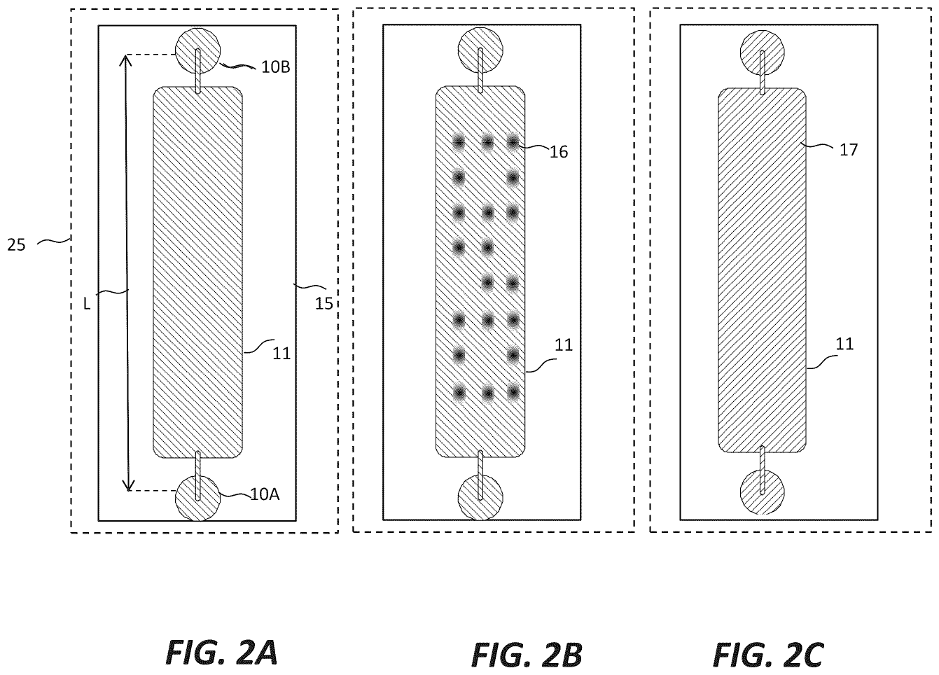

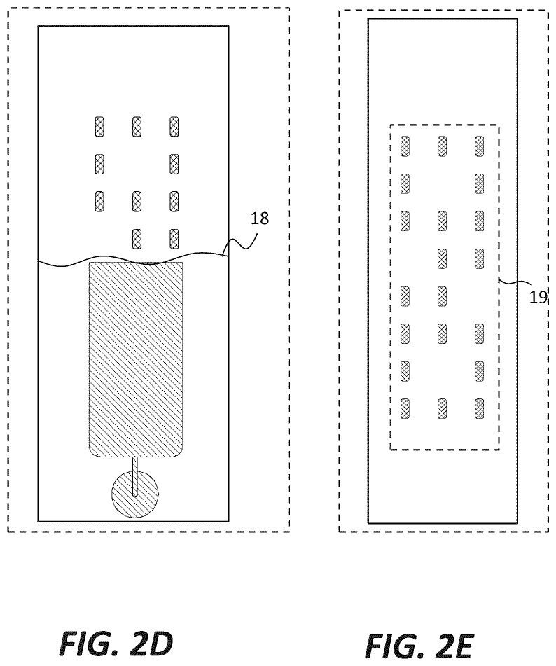

FIGS. 2A through 2E illustrate schematics of selective sintering of micro-molded structures in accordance with an embodiment. FIG. 2A shows a micro-molded structure 11 on a surface 15 of a substrate 25. The nanoparticle ink can be deposited through the inlet and outlet ports 10A and 10B. FIG. 2B shows local sintering and/or spot heating of select areas 16 of the structure 11. FIG. 2C shows the sintered areas 17 within the micro-molded structure 11. FIG. 2D shows the chemical removal of un-sintered structures using a solvent/etchant/washing reagent 18. FIG. 2E shows the remaining sintered structures 19 on the substrate surface. Local sintering enables the formation of the discrete structures 19 comprising nanoparticles.

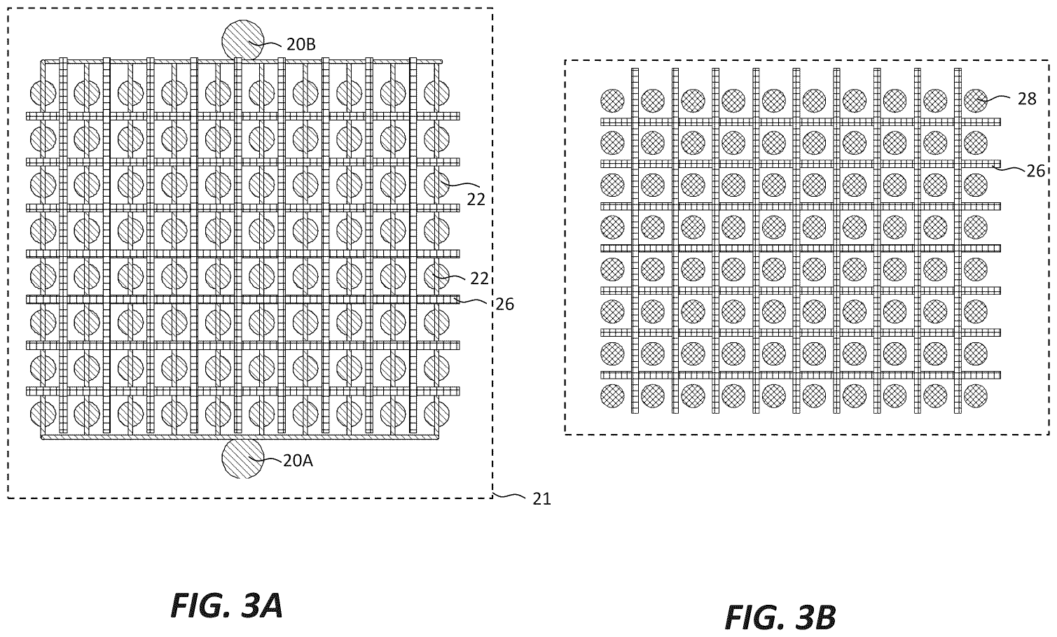

In several embodiments, micro-molded nanoparticle features can be deposited onto a device containing sensitive elements such as (but not limited to) bond pads, suspended membranes, and/or cantilevers. Selective removal of the micro-molded features in accordance with many embodiments eliminates the need for designing the micro-grooves in the stamp in such a way that they route the nanoparticle ink around sensitive areas. FIGS. 3A and 3B illustrate formation of nanoparticle structures on substrate with sensitive elements in accordance with an embodiment of the invention. FIG. 3A shows the micro-molded nanoparticle structures 22 on a surface 21. The structures 22 cross a number of sensitive areas 26. FIG. 3B shows the result of selective removal, leaving only the structures in the desired area 28, where there is no overlap with the sensitive areas 26 on the substrate. Due to the dimensions of the inlet port 20A and outlet port 20B being larger than the area between the sensitive areas, conventional sintering of all nanoparticle structures would not be able to achieve the desired area 28. Selective removal of micro-molded nanoparticles made it possible to achieve the desired area 28 with no overlapping with the sensitive areas 26.

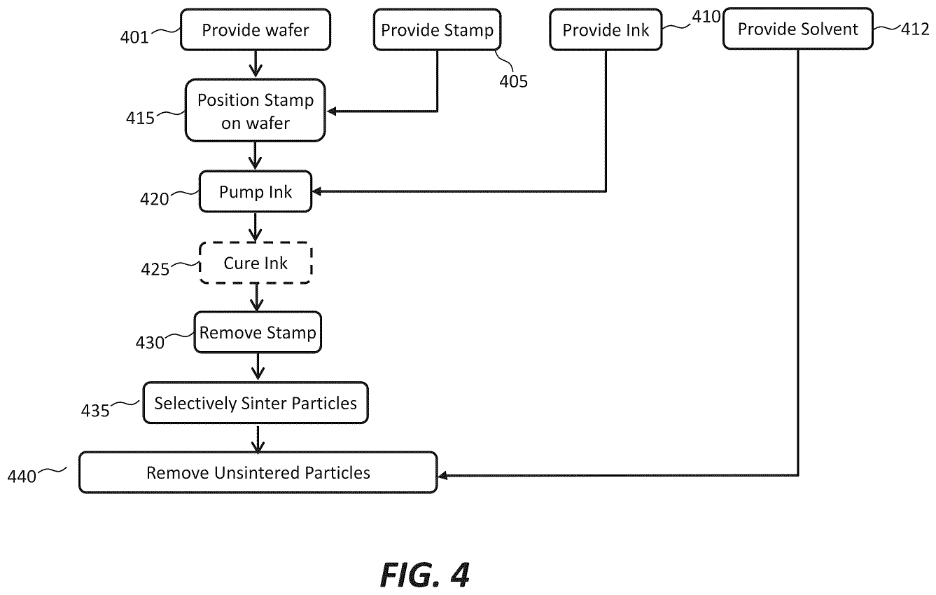

FIG. 4 illustrates a micro-molding and selective sintering and removal process in accordance with an embodiment. The fabrication process starts by providing (401) a substrate. The substrate can be any form of a substrate containing semiconductor materials or microelectronic devices. Examples of the substrate include (but are not limited to) wafer, silicon wafer, crystalline silicon, doped silicon, silicon oxide, silicon nitride, silicon carbide, glass, quartz, sapphire, aluminum oxide, germanium, and/or gallium arsenide. In some embodiment the substrate surface may be part of a chip on which a single microelectronic circuit or device is integrated. In other embodiments substrate surface may comprise a wafer containing multiple, possibility distinct, microelectronic circuits or devices.

Provide (405) a stamp and position (415) the stamp on the substrate. The stamp can be a micro-molding stamp. The stamp can be used to dispose microstructures on the substrate. Mold layer of the micro-molding stamp can be disposed in contact with (for example in conformal contact with) the substrate surface of the substrate.

Provide (410) an ink and pump (420) the ink into the stamp. The ink can contain nanoparticle materials to be deposited on to the substrate. The ink can be a nanoparticle ink comprising a suspension of nanoparticles in a liquid solvent. The nanoparticle ink can further comprises binders, dispersants, additives such as (but not limited to) polymeric additives, other solids, and/or solvent residues. The fraction of weight or volume of nanoparticle materials compared to the weight or volume of other components (such as solvents, dispersants, and other additives), may range between about 1% and about 95%; more specifically between about 20% and about 60%. Additives can be added to the ink to achieve desired solubility and/or viscosity and/or density and/or surface energy. The nanoparticles may have an average diameter ranging between about 1 nm and about 10000 nm; or between about 1 nm and about 10 nm; or between about 10 nm and about 300 nm; or between about 300 nm and about 1000 nm; or between about 1000 nm and about 10000 nm.

The nanoparticle ink can be pumped and/or dispensed through inlet ports of the stamp. As nanoparticles move through the channels, solvent in nanoparticle ink can diffuse into the mold layer so that the nanoparticles become tightly packed in the channels. Substantial wetting of the channels by the ink can be important to achieving the desired shape and facilitating fast extraction of the solvent. In some embodiments, micro-molding stamps with one or more ink distribution layers comprising a set of microchannels or reservoirs can route ink from inlet and outlet ports to channels and/or grooves.

The process can be accelerated by curing (425) the ink. The ink can be cured within the microchannels at temperatures ranging from about 20° C. to about 40° C.; or greater than about 40° C. The curing process in accordance with some embodiments includes (but not limited to) exposure the nanoparticle ink to heat, and/or to electromagnetic radiation. Examples of electromagnetic radiation include (but are not limited to) a xenon flash, infrared radiation, ultraviolet radiation, or laser radiation. During the curing processes, the solvent of the nanoparticle ink can be driven off from the nanoparticle ink and/or the mold layer. In some embodiments, the driven off solvent can be absorbed (at least in part) by the mold layer of the micro-molding stamp. In some embodiments, curing may not be necessary to form the microstructures. In some embodiments, local heating is applied while the stamp is placed on the substrate to enhance the curing in a desired region. This could be done with local hot plates and/or radiation. For radiation, the stamp can have different absorption spectra than the illumination source. The process of local laser heating can be optimized to allow nanoparticles to absorb the light or the solvent, based on the final applications.

Remove (430) the stamp once nanoparticles are deposited. The microstructures can be free-standing structures on the substrate without having supporting structures and/or walls. The deposited microstructures can have the patterns and geometries of the microchannels.

Selectively sinter (435) the particles. Substrate containing the microstructures can be selectively sintered to form the desired discrete structures, geometries, morphology, and/or pore sizes. Selective sintering and/or fusing nanoparticles in accordance with certain embodiments can be accomplished by exposing nanoparticles to local heat, localized UV radiation, or localized laser radiation. In a number of embodiments, selective sintering processes can be performed within a protective atmosphere including (but not limited to) in inert gases, in reactive gasses, or in vacuum in order to protect and/or prepare the surface of the features. Examples of gases include (but are not limited to) nitrogen, helium, argon, hydrogen, and carbon dioxide. One or more heating sources can be used for local sintering. Selective sintering temperatures can vary based on the heat sources used. Sintering can be carried out at temperatures from about 80° C. to about 700° C.; or from about 80° C. to about 600° C.; or from about 80° C. to about 550° C.; or from about 80° C. to about 500° C.; or from about 80° C. to about 100° C.; or from about 100° C. to about 200° C.; or from about 200° C. to about 500° C.; or from about 500° C. to about 700° C.

Provide washing solvent (412) to the substrate. The solvent can remove unsintered nanoparticles (440). Removing the unsintered nanoparticles can form the desired microstructures.

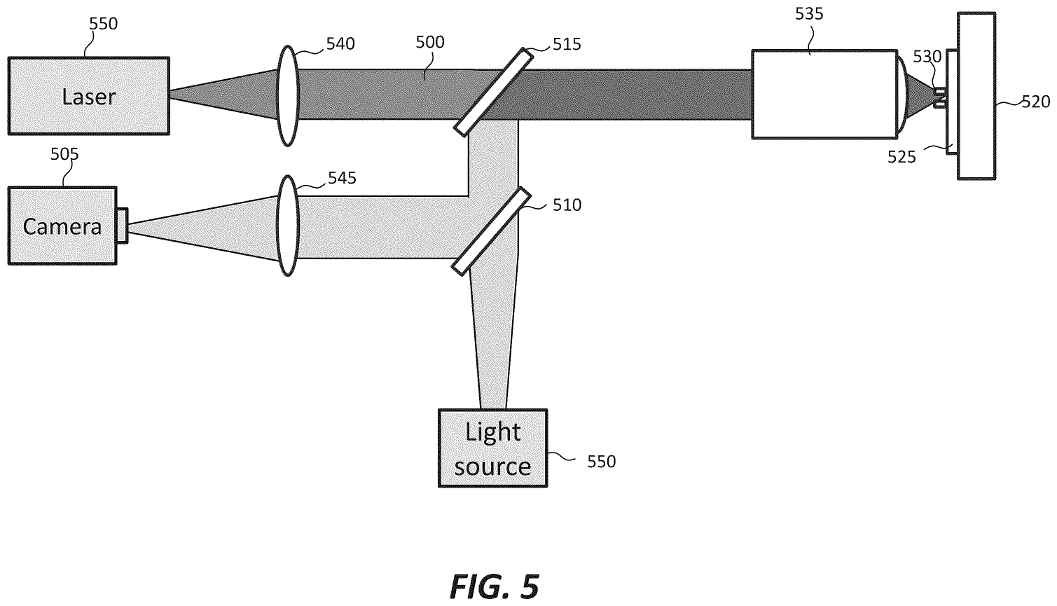

FIG. 5 illustrates a setup for selective sintering in accordance with an embodiment. In FIG. 5, a collimated laser beam 500 can be used in conjunction with a microscope objective 535 to focus light onto a small spot on the substrate 525 containing micro-molded nanoparticle feature 530. By moving the sample stage 520 the laser beam is scanned across the substrate to illuminate areas in which the nanoparticles should be sintered. A camera 505 can be used together with (dichroic) beam splitters 510 and 515, and a light source 550 to image the area of the sample being sintered by the laser beam, both to aim the beam correctly and monitor changes in the optical properties such as (but not limited to) the refractive index and/or absorption of the nanoparticles being sintered, which provides an indication of the degree of sintering.

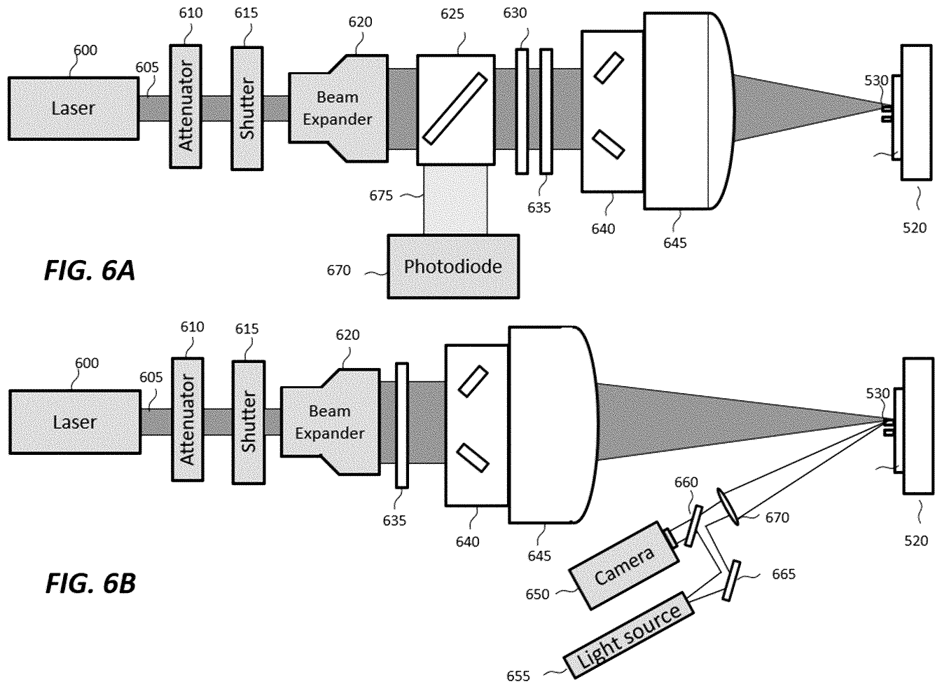

FIGS. 6A and 6B illustrate alternative setups for selective sintering in accordance with an embodiment. In FIGS. 6A and 6B, a collimated laser beam 605 is focused on the substrate employing f-theta lens or telecentric f-theta lens 645. In several embodiments, the spot is scanned across the substrate in regions in which nanoparticles should be sintered, by using a 2D galvo-mirror system 640. In some embodiments, the galvo mirrors are adjusted while shutter 615 is closed, so that after shutter 615 is opened, a specific spot on the surface is exposed to the beam for a predetermined amount of time. The heating time of a single structure can be between about 1 microsecond and about 10 seconds, more specifically, between about 100 microseconds and about 100 milliseconds. The heating time can be adjusted by adjusting the scanning speed of the beam, or by adjusting the shutter opening time. The size and depth-of-focus of the laser spot can be tuned by using a beam expander 620, enabling the sintering on larger or smaller areas, and thicker nanoparticle coatings. The spot size of the beam on the substrate can be between about 500 nm and about 50 microns, more specifically between about 5 microns and about 50 microns. The radiation intensity on the desired region can be controlled with an attenuator 610 to achieve the optimum temperature for sintering. The intensity profile of the laser in the focused region can be optimized using an optical beam shaper 635, such as a diffractive diffuser, refractive optics, Fourier optics, and micro-lenses to ensure a uniform temperature over the sintered region. The sintered region is monitored through either a photodiode 670 or camera 650 to monitor the evolution of the sintering area during sintering or control over the area under illumination. Like the previous example, this happens through changes in the optical properties, for example, the refractive index or absorption, of the nanoparticles being sintered, which provides an indication of the degree of sintering.

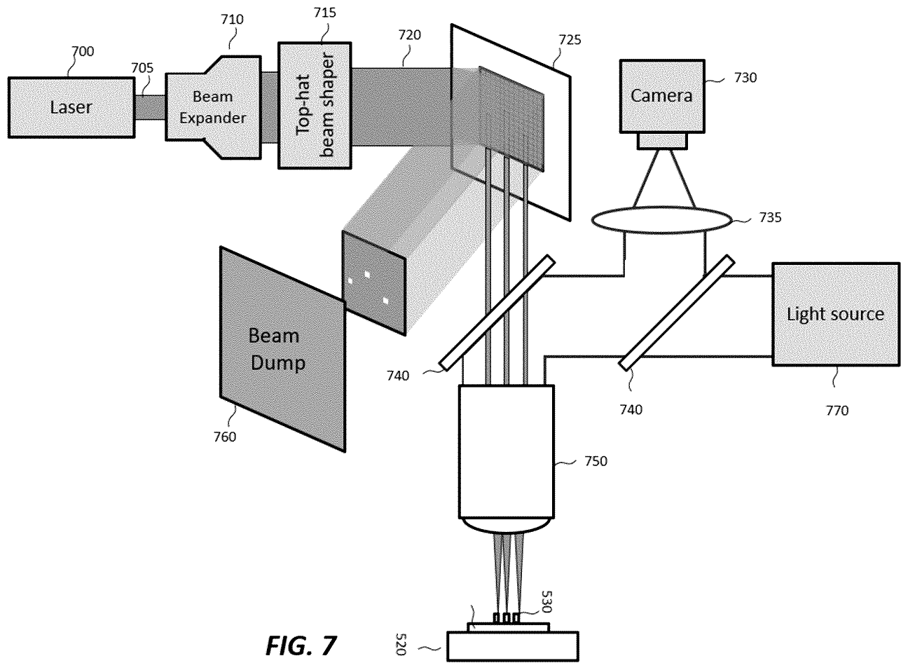

FIG. 7 illustrates an alternative setup for selective sintering in accordance with an embodiment. In FIG. 7, a collimated laser beam 705 path through a combination of beam expander 710 and beam shaper 715 to have a top-hat (flat-top) intensity profile 720 over the desired cross-section of the beam. This modified beam is illuminated over a digital micromirror device 725, which allows to control separately each micromirror by employing a signal. A set of mirrors from the image needs to sinter over the surface by reflecting into the optical lens and later on the substrate, and the rest of the beam reflects into the beam dump 760. The size of the image of each mirror on the substrate can be tuned by using a proper objective lens, and the intensity of the light over the sintering area can be controlled by the number of mirrors aimed at one region. Using a camera or thermal camera incorporating a white light makes it possible to monitor the sintering region or the evolution of that region over the entire course of sintering. Due to large numbers of micromirrors, it is possible to sinter many desired regions at one time within the view angle of the objective lens.

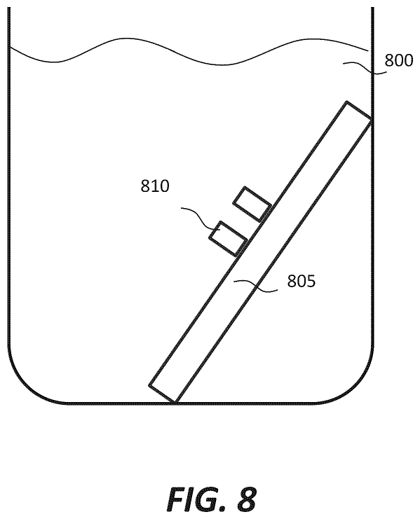

FIG. 8 illustrates a washing process to remove the un-sintered structures in accordance with an embodiment. FIG. 8 shows a substrate 805 with micro-molded nanoparticle features 810 during chemical washing in a solvent 800. The solvent 800 can remove any un-sintered nanoparticles such that sintered nanoparticle features 810 are preserved.

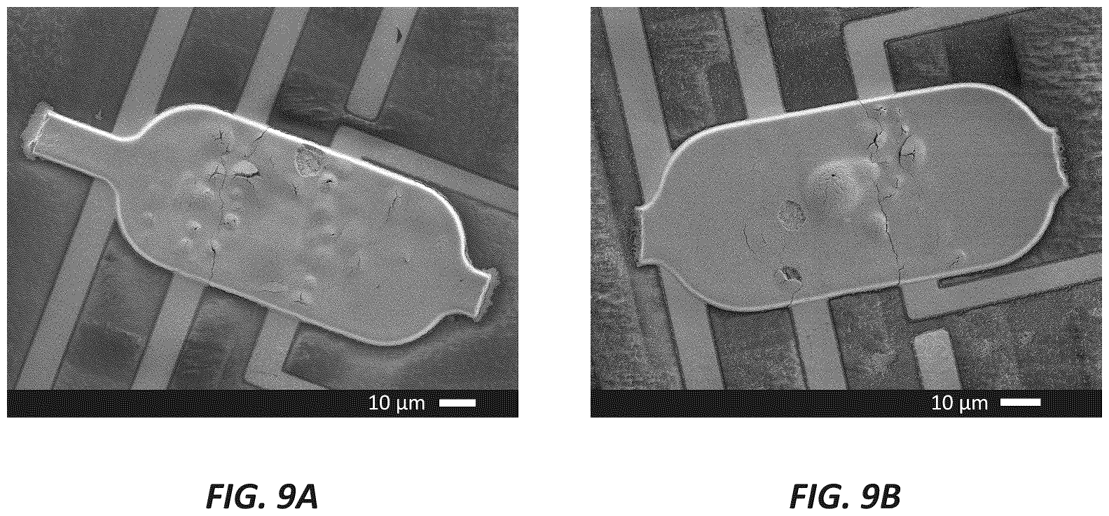

FIGS. 9A and 9B illustrate scanning electron microscope images of selective modified microstructures in accordance with an embodiment. FIGS. 9A and 9B show the standing micro-molded microstructures made of nanoparticles on a thin membrane, after locally heating and removing the unwanted regions. FIG. 9A shows that with the extension of time or heating parameters, the selective modification processes can increase the length of the microstructure and locally control the size of the structure.

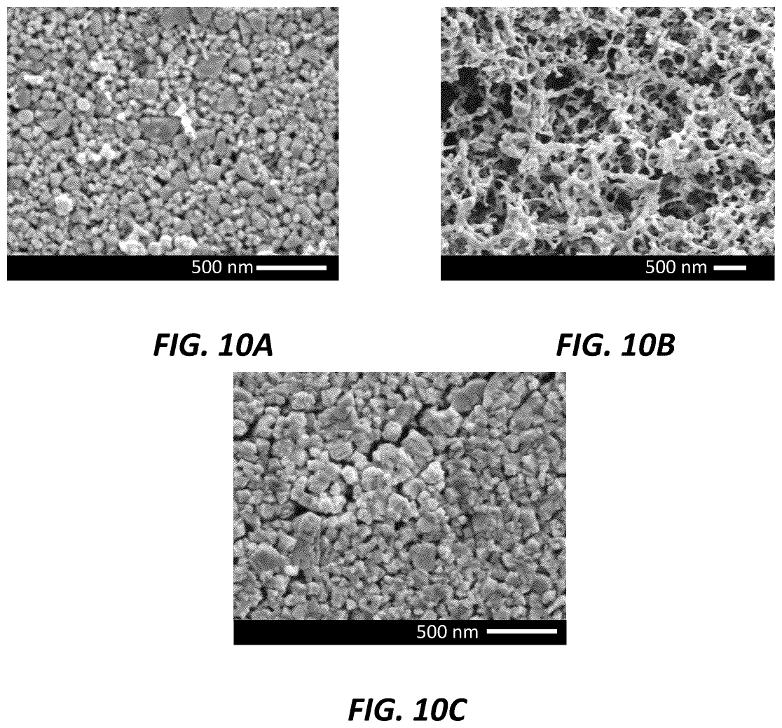

FIGS. 10A through 10C illustrate scanning electron microscope images of nanoparticles of different morphology and structures as a result of the selective modification processes in accordance with an embodiment. The selective modification processes can tune the morphology and nanostructure of micro-molded nanoparticles in a controlled manner, enabling the creation of nanostructures with tailored properties for specific applications.

### DOCTRINE OF EQUIVALENTS

This description of the invention has been presented for the purposes of illustration and description. It is not intended to be exhaustive or to limit the invention to the precise form described, and many modifications and variations are possible in light of the teaching above. The embodiments were chosen and described in order to best explain the principles of the invention and its practical applications. This description will enable others skilled in the art to best utilize and practice the invention in various embodiments and with various modifications as are suited to a particular use. The scope of the invention is defined by the following claims.

As used herein, the singular terms “a,” “an,” and “the” may include plural referents unless the context clearly dictates otherwise. Reference to an object in the singular is not intended to mean “one and only one” unless explicitly so stated, but rather “one or more.”

As used herein, the terms “approximately” and “about” are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

What is claimed is:

1. A method for selectively modifying nanoparticle structures, comprising:
depositing a structure of a continuous pattern comprising nanoparticles on a substrate;
applying a heat to a first portion of the structure, wherein the heat selectively sinters the nanoparticles in the first portion; and
removing nanoparticles that are not sintered such that the sintered first portion of the structure forms a discrete pattern.

2. The method of claim 1, wherein the structure of continuous pattern is deposited by a micro-molding process, a microchannel particle deposition process, a screen-printing process, a spin coating process, a blade coating process, an ink-jet printing process, or an aerosol jet printing process.

3. The method of claim 1, wherein the heat is a localized heat provided by a micro hotplate, a masked light source, a UV light source, a masked UV source, a visible light source, an infrared light source, a laser, a focused laser beam, or a magnetic induction.

4. The method of claim 1, wherein the heat is a localized heat provided by a UV light with a wavelength that matches a plasmonic frequency of the nanoparticles.

5. The method of claim 3, wherein the laser has a wavelength range selected from the group consisting of: from 100 nm to 400 nm, from 380 nm to 700 nm, and from 780 nm to 1 mm; wherein the laser has a pulsation condition selected from the group consisting of: a continuous wave laser, a nanosecond laser, a picosecond laser, and a femtosecond laser.

6. The method of claim 1, further comprising heating the substrate up to 150° C. to remove non-nanoparticle substances prior to applying the heat.

7. The method of claim 1, wherein the heat is between 100° C. and 1000° C.

8. The method of claim 1, wherein the nanoparticles comprise metal nanoparticles, metal-oxide nanoparticles, metal alloy nanoparticles, or any combinations thereof.

9. The method of claim 1, wherein the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt.

10. The method of claim 1, wherein the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxide.

11. The method of claim 1, wherein the nanoparticles have an average diameter between 1 nm and 10 microns.

12. The method of claim 1, wherein the continuous pattern further comprises at least one material selected from the group consisting of: dispersants, binders, polymers, solids, and solvent residues.

13. The method of claim 1, wherein removing is a chemical removal process or a mechanical removal process.

14. The method of claim 13, wherein the chemical removal process comprises a solvent selected from the group consisting of: water, isopropanol, acetone, ethanol, ethylene glycol, methyl ethyl ketone, diethylene glycol monomethyl ether, dimethyl sulfoxide, trichloroethylene, tetrachloroethylene, hexane, toluene, sodium hydroxide, potassium hydroxide, acetic acid, citric acid, and a combination thereof.

15. The method of claim 14, wherein the solvent comprises a surfactant selected from the group consisting of: an anionic surfactant, a nonionic surfactant, a cationic surfactant, an amphoteric surfactant, and a combination thereof.

16. The method of claim 13, wherein the mechanical removal process comprises using ultrasonic energy or peeling with an adhesive layer.

17. The method of claim 1, wherein a minimum distance among the discrete pattern is between 1 micrometer and 100 micrometers.

18. The method of claim 1, wherein the substrate comprises one or more functional electronic elements and the discrete pattern does not overlap with the one or more functional electronic elements.

19. A method for selectively modifying nanoparticle structures, comprising:
depositing a structure of a continuous pattern comprising nanoparticles on a substrate;
applying an adhesive mask onto the structure;
applying a heat to a first portion of the adhesive mask, wherein the heat selectively activates the adhesives in the first portion such that the first portion of the adhesive mask binds to the nanoparticles; and
removing the nanoparticles of the first portion by removing the adhesive mask such that a remaining portion forms a discrete pattern.

20. The method of claim 19, wherein the structure of continuous pattern is deposited by a micro-molding process, a microchannel particle deposition process, a screen-printing process, a spin coating process, a blade coating process, an ink-jet printing process, or an aerosol jet printing process.

21. The method of claim 19, wherein the heat is a localized heat provided by a micro hotplate, a masked light source, a UV light source, a masked UV source, a visible light source, an infrared light source, a laser, a focused laser beam, or a magnetic induction.

22. The method of claim 19, wherein the heat is a localized heat provided by a UV light with a wavelength that matches a plasmonic frequency of the nanoparticles.

23. The method of claim 21, wherein the laser has a wavelength range selected from the group consisting of: from 100 nm to 400 nm, from 380 nm to 700 nm, and from 780 nm to 1 mm; wherein the laser has a pulsation condition selected from the group consisting of: a continuous wave laser, a nanosecond laser, a picosecond laser, and a femtosecond laser.

24. The method of claim 19, wherein the nanoparticles comprise metal nanoparticles, metal-oxide nanoparticles, metal alloy nanoparticles, or any combinations thereof.

25. The method of claim 19, wherein the nanoparticles comprise at least one element selected from the group consisting of: zinc, aluminum, yttrium, lanthanum, iron, molybdenum, niobium, tungsten, tantalum, manganese, titanium, zirconium, tin, nickel, chromium, cerium, platinum, and cobalt.

26. The method of claim 19, wherein the nanoparticles comprise at least one material selected from the group consisting of: micro porous silica, mesoporous silica, silicon dioxide, porous glass, activated carbon, synthetic zeolite, natural zeolite, aluminosilicate mineral, aluminosilicate clay, montmorillonite, halloysite), copper oxide, palladium oxide, platinum oxide, and iron oxide.

27. The method of claim 19, wherein the nanoparticles have an average diameter between 1 nm and 10 microns.

28. The method of claim 19, wherein the continuous pattern further comprises at least one material selected from the group consisting of: dispersants, binders, polymers, solids, and solvent residues.

29. The method of claim 19, wherein a minimum distance among the discrete pattern is between 1 micrometer and 100 micrometers.
